(19) United States
(12) Patent Application Publication
(10) Pub. No.: US 2018/0002161 A1
(43) Pub. Date: Jan. 4, 2018

(54) MEMS DEVICE AND PROCESS

(71) Applicant: Cirrus Logic International Semiconductor Ltd., Edinburgh (GB)

(72) Inventors: Colin Robert JENKINS, Linlithgow (GB); Scott Lyall CARGILL, Edinburgh (GB); Clive Robert GRAHAM, Edinburgh (GB)

(73) Assignee: Cirrus Logic International Semiconductor Ltd., Edinburgh (GB)

(21) Appl. No.: 15/636,887

(22) Filed: Jun. 29, 2017

Related U.S. Application Data
(60) Provisional application No. 62/408,955, filed on Oct. 17, 2016.

(30) Foreign Application Priority Data
Jun. 30, 2016 (GB) 1611412.6
Jun. 30, 2016 (GB) PCT/GB2016/051974
Nov. 17, 2016 (GB) 1619467.2
Jun. 19, 2017 (GB) 1709735.3

(51) Int. Cl. B81B 3/00; B81C 1/00; B81C 3/00; H04R 31/00; H04R 19/04

(52) U.S. Cl. CPC B81B 3/0021; H04R 31/006; H04R 19/04; B81C 3/001; B81C 1/00158; B81B 2203/0127

(57) ABSTRACT

The present application describes MEMS transducer having a membrane and a membrane electrode. The membrane and membrane electrode form a two-layer structure. The membrane electrode is in the form of a lattice of conductive material. The pitch of the lattice and/or the size of the openings varies from a central region of the membrane electrode to a region laterally outside the central region.

### FIELD OF DISCLOSURE

This invention relates to a micro-electro-mechanical system (MEMS) device and process, and in particular to a MEMS device and process relating to a transducer, for example a capacitive microphone.

### BACKGROUND

Various MEMS devices are becoming increasingly popular. MEMS transducers, and especially MEMS capacitive microphones, are increasingly being used in portable electronic devices such as mobile telephones and portable computing devices.

Microphone devices formed using MEMS fabrication processes typically comprise one or more membranes with electrodes for read-out/drive deposited on the membranes and/or a substrate. In the case of MEMS pressure sensors and microphones, the read out is usually accomplished by measuring the capacitance between a pair of electrodes which will vary as the distance between the electrodes changes in response to sound waves incident on the membrane surface.

FIGS. 1a and 1b show a schematic diagram and a perspective view, respectively, of a known capacitive MEMS microphone device 100. The capacitive microphone device 100 comprises a membrane layer 101 which forms a flexible membrane which is free to move in response to pressure differences generated by sound waves. A first electrode 102 is mechanically coupled to the flexible membrane, and together they form a first capacitive plate of the capacitive microphone device. A second electrode 103 is mechanically coupled to a generally rigid structural layer or back-plate 104, which together form a second capacitive plate of the capacitive microphone device. In the example shown in FIG. 1a the second electrode 103 is embedded within the back-plate structure 104.

The capacitive microphone is formed on a substrate 105, for example a silicon wafer which may have upper and lower oxide layers 106, 107 formed thereon. A cavity 108 in the substrate and in any overlying layers (hereinafter referred to as a substrate cavity) is provided below the membrane, and may be formed using a “back-etch” through the substrate 105. The substrate cavity 108 connects to a first cavity 109 located directly below the membrane. These cavities 108 and 109 may collectively provide an acoustic volume thus allowing movement of the membrane in response to an acoustic stimulus. Interposed between the first and second electrodes 102 and 103 is a second cavity 110.

The first cavity 109 may be formed using a first sacrificial layer during the fabrication process, i.e. using a material to define the first cavity which can subsequently be removed, and depositing the membrane layer 101 over the first sacrificial material. Formation of the first cavity 109 using a sacrificial layer means that the etching of the substrate cavity 108 does not play any part in defining the diameter of the membrane. Instead, the diameter of the membrane is defined by the diameter of the first cavity 109 (which in turn is defined by the diameter of the first sacrificial layer) in combination with the diameter of the second cavity 110 (which in turn may be defined by the diameter of a second sacrificial layer). The diameter of the first cavity 109 formed using the first sacrificial layer can be controlled more accurately than the diameter of a back-etch process performed using a wet-etch or a dry-etch. Etching the substrate cavity 108 will therefore define an opening in the surface of the substrate underlying the membrane 101.

A plurality of holes, hereinafter referred to as bleed holes 111, connect the first cavity 109 and the second cavity 110.

As mentioned the membrane may be formed by depositing at least one membrane layer 101 over a first sacrificial material. In this way the material of the membrane layer(s) may extend into the supporting structure, i.e. the side walls, supporting the membrane. The membrane and back-plate layer may be formed from substantially the same material as one another, for instance both the membrane and back-plate may be formed by depositing silicon nitride layers. The membrane layer may be dimensioned to have the required flexibility whereas the back-plate may be deposited to be a thicker and therefore more rigid structure. Additionally various other material layers could be used in forming the back-plate 104 to control the properties thereof. The use of a silicon nitride material system is advantageous in many ways, although other materials may be used, for instance MEMS transducers using polysilicon membranes are known. In some applications, the microphone may be arranged in use such that incident sound is received via the back-plate. In such instances a further plurality of holes, hereinafter referred to as acoustic holes 112, are arranged in the back-plate 104 so as to allow free movement of air molecules, such that the sound waves can enter the second cavity 110. The first and second cavities 109 and 110 in association with the substrate cavity 108 allow the membrane 101 to move in response to the sound waves entering via the acoustic holes 112 in the back-plate 104. In such instances the substrate cavity 108 is conventionally termed a “back volume”, and it may be substantially sealed.

In other applications, the microphone may be arranged so that sound may be received via the substrate cavity 108 in use. In such applications the back-plate 104 is typically still provided with a plurality of holes to allow air to freely move between the second cavity and a further volume above the back-plate.

It should also be noted that whilst FIG. 1 shows the back-plate 104 being supported on the opposite side of the membrane to the substrate 105, arrangements are known where the back-plate 104 is formed closest to the substrate with the membrane layer 101 supported above it.

In use, in response to a sound wave corresponding to a pressure wave incident on the microphone, the membrane is deformed slightly from its equilibrium or quiescent position. The distance between the membrane electrode 102 and the backplate electrode 103 is correspondingly altered, giving rise to a change in capacitance between the two electrodes that is subsequently detected by electronic circuitry (not shown). The bleed holes allow the pressure in the first and second cavities to equalise over a relatively long timescale (in acoustic frequency terms) which reduces the effect of low frequency pressure variations, e.g. arising from temperature variations and the like, but without impacting on sensitivity at the desired acoustic frequencies.

The flexible membrane layer of a MEMS transducer generally comprises a thin layer of a dielectric material—such as a layer of crystalline or polycrystalline material. The membrane layer may, in practice, be formed by several sub-layers of material which are deposited in successive steps to form the membrane layer. The flexible membrane 101 may, for example, be formed from silicon nitride Si₃N₄ or polysilicon. Crystalline and polycrystalline materials have high strength and low plastic deformation, both of which are highly desirable in the construction of a membrane. The membrane electrode 102 of a MEMS transducer is typically a thin layer of metal, e.g. aluminium, which is typically located in the centre of the membrane 101, i.e. that part of the membrane which displaces the most. It will be appreciated by those skilled in the art that the membrane electrode may be formed by an alloy such as aluminium-silicon for example. The membrane electrode may typically cover, for example, around 40% of area of the membrane, usually in the central region of the membrane.

Thus, known transducer membrane structures are composed of two layers of different material—typically a dielectric layer (e.g. SiN) and a conductive layer (e.g. AlSi).

Typically the membrane layer 101 and membrane electrode 102 may be fabricated so as to be substantially planar in the quiescent position, i.e. with no pressure differential across the membrane, as illustrated in FIG. 1a. The membrane layer may be formed so as to be substantially parallel to the back-plate layer in this quiescent position, so that the membrane electrode 102 is parallel to the back-plate electrode 103. However, over time, the membrane structure may become deformed—e.g. as a consequence of relatively high or repeated displacement—so that it will not return to exactly the same starting position.

A number of problems are associated with the previously considered transducer designs. In particular both the membrane and the membrane electrode will suffer intrinsic mechanical stress after manufacture. As a consequence of the membrane and membrane electrode having greatly different thermal coefficients of expansion, mechanical stress arises within the structure following deposition, as the materials contract by different amounts on return to room temperature from high deposition temperatures of a few hundred degrees Celsius. As the two layers are intimately mechanically coupled together, thus preventing the dissipation of stress by independent mechanical contraction, the composite structure of electrode and membrane will tend to deform. This is similar to the well-known operation of bi-metallic strip thermostat sensors. Over a long time, especially when subject to repeated mechanical exercising as typical of a microphone membrane in use, the metal electrode layer in particular may be subject to creep or plastic deformation as it anneals to reduce its stored stress energy—being unable to release it in any other way. Thus, the equilibrium or quiescent position of the membrane structure comprising the membrane and the membrane electrode is sensitive to manufacturing conditions from day one and can also change over time.

FIG. 2 illustrates the permanent deformation which can occur to the quiescent position of the membrane 101/102. It can be seen that the quiescent position of the membrane, and thus the spacing between the back-plate electrode 103 and the membrane electrode 102, therefore changes from its position immediately after manufacture—shown by the dashed line—to the deformed quiescent position. This can lead to a DC offset in the measurement signal from such a transducer, as the capacitance at the quiescent position is not the same. More importantly, for a.c. audio signals, the change in capacitance leads to a variation in the signal charge for a given acoustic stimulus, i.e. the acousto-electrical sensitivity of the microphone.

In addition, the elasticity of the composite electrode-membrane structure 101/102 is sensitive to the mechanical stress of the electrode and membrane layers. Any variation in manufacturing conditions and the subsequent stress release via metal creep or suchlike will affect the values of the stress of these layers. The deformation due to the stress mismatch will also directly affect the values of quiescent stress.

Thus, it can be appreciated that the membrane structure and associated transducer may suffer an increased manufacturing variation in initial sensitivity and furthermore experience a change—or drift—in sensitivity over time meaning that the transducer performance cannot be kept constant.

Furthermore, the metal of the membrane electrode may undergo some plastic deformation as a consequence of relatively high or repeated displacement from the quiescent/equilibrium position. Thus, the metal of the membrane electrode may be deformed so it will not return to its original position. Since the flexible membrane 101 and the membrane electrode 102 are mechanically coupled to one another this can also lead to an overall change in the quiescent position of the flexible membrane 101 and/or a change in the stress properties and thus the elasticity of the overall membrane structure.

FIG. 3a shows a top view of a previously considered membrane structure comprising a planar membrane layer 301 and an electrode 302. The electrode—which is typically formed of metal or metal alloy—is patterned to incorporate a plurality of openings 313. In this specific example the openings are generally hexagonal in shape. By providing such openings in the membrane electrode, the total amount of metal forming the membrane electrode can be reduced compared to a membrane electrode having a similar size diameter but without any such openings, i.e. the membrane electrode having the openings provides less coverage of the flexible membrane. This in turn will lead to a membrane and membrane electrode structure which has reduced plastic deformation.

It will be appreciated that microphone sensitivity in terms of signal charge is a function of capacitance which is directly proportional to the area of the conductive electrode. Transducer structures which incorporate a membrane having a patterned electrode layer may therefore potentially demonstrate a lower sensitivity and/or performance of the transducer as compared to sheet electrode designs.

### SUMMARY

The present disclosure relates to MEMS transducers and processes which seek to alleviate some of the aforementioned disadvantages, for example by providing a transducer which exhibits has a reduced plastic deformation as compared to sheet electrode designs but which also demonstrate an improved sensitivity or performance.

According to a first aspect there is provided a MEMS transducer comprising a membrane layer and a membrane electrode formed of a conductive material on a surface of the membrane layer, the membrane electrode having a plurality of openings provided therein, wherein a ratio of an area of the conductive material relative to an area of the openings decreases from a first said ratio in a first region at or near a central region of the membrane layer to a second said ratio in a second region laterally outside the first region.

Thus, the membrane electrode is provided with a plurality of holes or perforations. The openings extend through the plane of the electrode and expose an area of the underlying membrane layer which substantially corresponds to the area of the opening.

The ratio of the area of the conductive material forming the membrane electrode relative to the area of the openings (or the exposed area of the underlying membrane layer)—in other words the “electrode to membrane area ratio”—varies between the first and second regions of the membrane electrode.

The membrane layer forms a flexible membrane of the transducer device. The transducer comprises a layer of membrane material which may be supported in a fixed relation relative to an underlying substrate of the substrate. The membrane material may extend over a cavity that is provided in the substrate. The region of the membrane which extends over the cavity may be considered to form the flexible membrane of the transducer. The central region of the membrane layer which overlies the centre of the substrate cavity is the part of the membrane that displaces the most in response to an acoustic pressure wave.

The ratio of the area of the material forming the membrane electrode to the area of the membrane layer is greater in a first region of the membrane electrode than in a second region of the membrane electrode. The first region is at or near the central region of the underlying membrane layer and the second region is laterally outside the central region of the underlying membrane layer. Thus, according to this arrangement, the central region of the membrane electrode advantageously comprises a greater area or areal density of metal and, thus, the capacitance is enhanced at the central region of the transducer.

The membrane electrode may comprise more than two regions. The additional regions may be provided concentrically around the central region of the membrane electrode such that the electrode to membrane area ratio varies gradually from the centre to the periphery of the membrane electrode. The electrode to membrane ratio may therefore decrease from the first region towards a region at or near the periphery of the membrane electrode. In other words, the electrode to membrane area ratio is smaller away from the central region of the membrane layer.

The variation—or change—in the ratio of the area of the material forming the membrane electrode relative to the area of the openings can be achieved in a number of ways.

For example, the size of the openings may vary between regions such that in a first region, where the size of the openings is relatively small, the ratio of the area of the membrane electrode material relative to the area of the openings is relatively large. Conversely, in a second region, where the size of the openings is relatively large, the ratio of the area of the membrane electrode material relative to the area of the openings is relatively small. According to one particular example the openings provided in the membrane electrode increase in size from a region overlying the central region of the membrane layer to a region at or near the periphery of the membrane electrode.

Alternatively, or additionally, the pitch distance—i.e. the centre-to-centre distance or spacing between adjacent openings—may vary such that, in a first region where the distance between adjacent openings is relatively small, the ratio of the area of the membrane electrode material relative to the area of the openings is relatively large. Conversely, in a second region, where the distance between corresponding points on adjacent openings is relatively large, the ratio of the area of the membrane electrode material relative to the area of the openings is relatively small. According to one particular example, the pitch distance between the centre of adjacent openings may increase from a region overlying the central region of the membrane layer to a region at or near the periphery of the membrane electrode. According to another particular the pitch distance increases away from the centre whilst the size of the openings also increases in order that the ratio of an area of the conducive material relative to an area of the openings still decreases from a first said ratio in a first region at or near a central region of the membrane layer to a second said ratio in a second region laterally outside the first region.

Thus, the membrane electrode layer may be considered to comprise a lattice of conductive material, wherein the lattice comprises a plurality of openings and wherein pitch of the lattice and/or the size of the openings varies from a central region of the membrane electrode to a region laterally outside the central region. The variation of the pitch and/or size of the openings is such that the ratio of an area of the conducive material relative to an area of the openings decreases from a first said ratio in a first region at or near a central region of the membrane layer to a second said ratio in a second region laterally outside the first region.

The MEMS transducer may comprise a back-plate structure wherein the flexible membrane is supported with respect to said back-plate structure. The back-plate structure may comprise a plurality of holes through the back-plate structure. Preferably, at least a part of the area of at least one opening in the membrane electrode corresponds to the area of at least one back-plate hole, in a direction normal to the membrane. Thus, the holes in the backplate may at least partially overlay the openings in the membrane electrode. It will be appreciated that the size of the backplate holes may be the same as the size of some of the openings in the membrane electrode, although these need not necessarily be the case.

The openings may be of any shape, for example circular or polygonal (e.g. square) in shape. In particular, the openings in the membrane electrode may be hexagonal in shape. According to one or more examples, the openings may exhibit a shape wherein the distance between any two diametrically opposite points on the outer edge of a given opening are substantially the same. According to one or more examples the openings can be considered to exhibit more than two orders of rotational symmetry.

The membrane electrode can thus be considered to be patterned to form the plurality openings. The membrane electrode can be considered to comprise a lattice, or a “lacy” structure. The membrane electrode can be considered to comprise a network of conductive material.

The flexible membrane may comprise a crystalline or polycrystalline material. Preferably the flexible membrane layer comprises silicon nitride. The membrane electrode may comprise metal or a metal alloy. Preferably, the electrode comprises aluminium, silicon, doped silicon or polysilicon.

Examples described herein advantageously demonstrate a reduction in the degree of deformation of the quiescent or equilibrium position of the membrane structure over time. Thus examples described herein advantageously reduce the area of interface between the membrane material and the metal electrode, as a consequence of the provided openings, thereby serving to reduce the mechanical influence of the metal electrode layer on the membrane layer. Thus, the time-dependent drift of the MEMS transducer caused by deformation of the two-layer structure is beneficially alleviated.

Furthermore, the examples described herein may demonstrate an enhancement in the capacitance, since the overall working area of the electrode layer—i.e. the amount of conductive material—can be advantageously increased compared to previous patterned electrodes having openings of a uniform pitch and size. This may be achieved e.g. by a reduction in the size of the openings which provides a corresponding increase in the amount of electrode material provided on the membrane—in one or more regions of the device. Alternatively, or additionally, this may be achieved by varying the distance between corresponding points on adjacent openings or groups of openings such that the amount of electrode material provided per unit area is increased in one or more regions of the device.

The variation in the electrode to membrane area ratio may take place gradually across the membrane. Thus, the variation may be measurable between all adjacent openings on a path from a first region of the electrode to a second region of the electrode. Alternatively, the variation in the electrode to membrane area ratio may be measurable between two or more groups of openings, for example the size of the openings of each group may be different. In this case, each group of openings can be considered to form a region of the membrane electrode.

The transducer may be a capacitive sensor such as a microphone. The transducer may comprise readout, e.g. amplification, circuitry. The transducer may be located within a package having a sound port, i.e. an acoustic port. The transducer may be implemented in an electronic device which may be at least one of: a portable device; a battery powered device; an audio device; a computing device; a communications device; a personal media player; a mobile telephone; a tablet device; a games device; and a voice controlled device.

According to an example of a further aspect there is provided a MEMS transducer comprising a membrane layer and a conductive membrane electrode layer. The membrane layer and membrane electrode layer form a two-layer structure. The membrane electrode is formed on a surface of the membrane layer. The membrane electrode layer has a plurality of openings provided therein. A ratio of an area of the conductive material of the membrane electrode layer relative to an area of the openings in the membrane electrode layer decreases from a first said ratio in a first region at or near a central region of the membrane layer to a second said ratio in a second region laterally outside the first region.

Features of any given aspect or example may be combined with the features of any other aspect or example and the various features described herein may be implemented in any combination in a given example.

Associated methods of fabricating a MEMS transducer are provided for each of the above aspects or examples.

### BRIEF DESCRIPTION OF THE DRAWINGS

For a better understanding of the present invention and to show how the same may be carried into effect, reference will now be made by way of example to the accompanying drawings in which:

FIGS. 1a and 1b illustrate known capacitive MEMS transducers in section and perspective views;

FIG. 2 illustrates how a membrane may be deformed;

FIG. 3a illustrates a plan view of a previously considered membrane electrode structure;

FIG. 3b illustrates a cross section through a membrane electrode structure that is patterned to incorporate openings;

FIG. 4 shows a cross section through a membrane electrode structure according to a first example;

FIGS. 5a, 5b and 5c show the variation in the size of a series of substantially square-shaped openings that are provided diametrically across a membrane electrode according to second and third examples; and

FIG. 6 shows illustrates a partial plan view of a membrane electrode structure according to a fourth example.

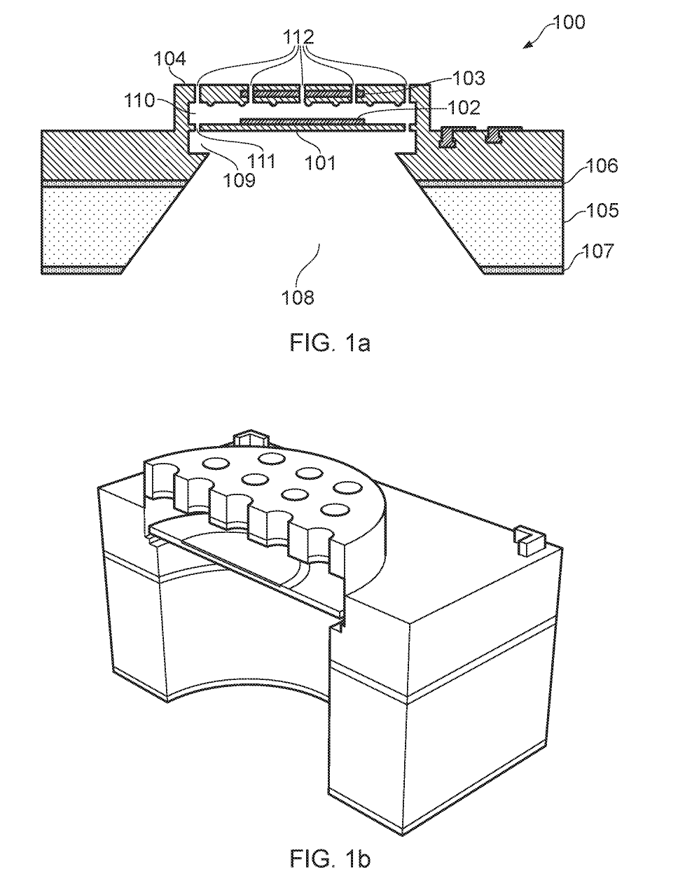

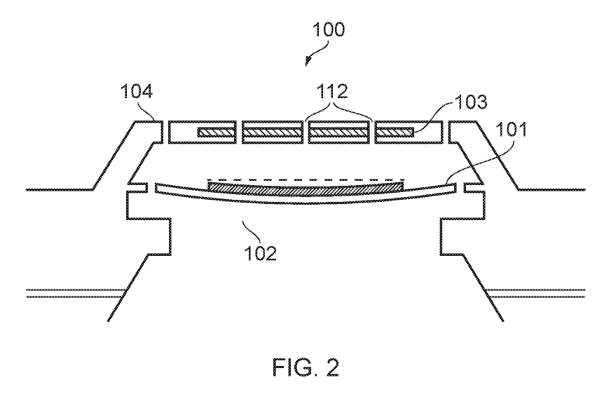

Throughout this description any features which are similar to features in other figures have been given the same reference numerals.

### DETAILED DESCRIPTION

Examples will be described in relation to a MEMS transducer in the form of a MEMS capacitive microphone. It will be appreciated, however, that the present examples are equally applicable to other types of MEMS transducer including capacitive-type transducers.

As mentioned above for MEMS sensors having a metal membrane electrode provided on a flexible membrane layer, especially a membrane layer which is a crystalline material, plastic deformation of the metal in use may mean that the quiescent position of the membrane and/or stress characteristics can change overtime with use. This can result in an unwanted DC offset and/or a change in sensitivity of the sensor and the subsequent quality of the acoustic signal being reproduced may be significantly degraded.

In an earlier application filed by the present Applicant a MEMS transducer was disclosed in which the membrane electrode comprises at least one opening, wherein at least part of the area of the opening corresponds to the area of a back-plate hole in a direction normal to the membrane. In other words the area of at least part of the opening in the membrane electrode aligns (in a direction normal to the membrane) with at least part of the area of a back-plate hole. By providing such openings in the membrane electrode, the total amount of metal forming the membrane electrode can be reduced compared to a membrane electrode having a similar diameter but without any such openings, i.e. the membrane electrode having the openings provides less coverage of the flexible membrane.

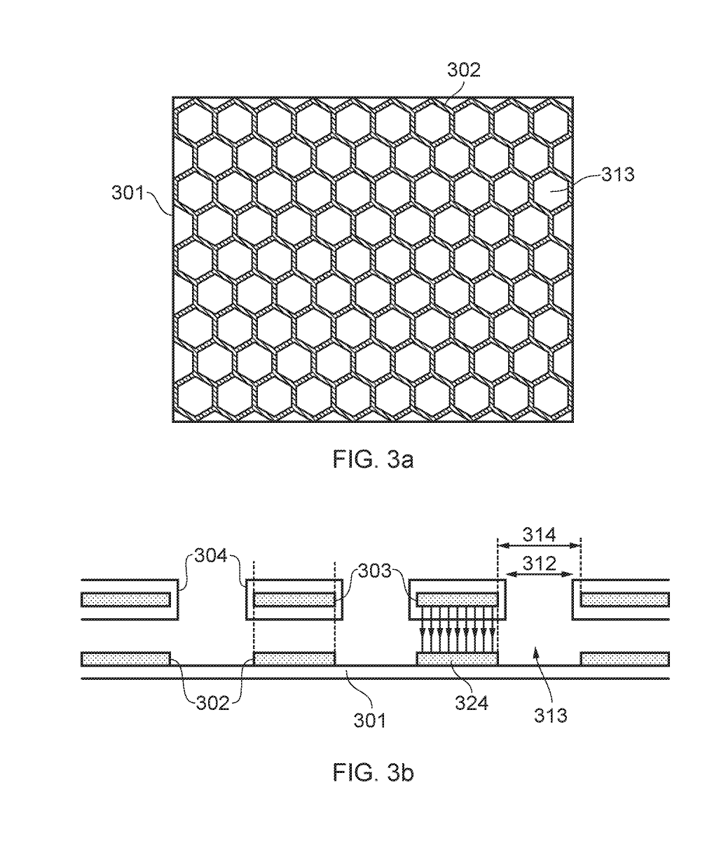

FIGS. 3a and 3b illustrate plan and cross-sectional view respectively of such a previously proposed MEMS transducer comprising a membrane electrode 302 formed on a flexible membrane 301. The membrane electrode 302 has a plurality of openings 313 in the electrode material 302 where there is no coverage of the membrane 301. These openings (or areas of absence) 313 reduce the amount of electrode material 302 which is deposited on the membrane 301 (for a given diameter of electrode) and therefore increase the proportion of membrane material to electrode material compared to the electrode without such openings. This in turn will lead to a membrane structure 301/302 which has reduced plastic deformation. In use this structure will 301/302 is expected to deform less and this improve the operation of the MEMS transducer 100 compared to a membrane electrode without openings.

FIG. 3b shows a membrane electrode 302 formed on a flexible membrane 301, and additionally shows the back-plate 304 and back-plate electrode 303 which have acoustic holes 312 through them. These acoustic holes 312 allow acoustic communication between the cavity between the membrane and back-plate and a volume on the other side of the membrane (which could be a sound port or a back-volume). The acoustic holes 312 extend through both the back-plate 304 and the back-plate electrode 303, and thus there are holes through the entire back-plate structure 303/304. As one skilled in the art will appreciate, and as illustrated in FIG. 3b, in a parallel plate capacitor which is charged/biased there will be an electrostatic field component running from one plate to the other in a direction perpendicular to the plates.

A number of potential disadvantages have been identified in connection with some examples of the previously considered design. Specifically, it will be appreciated that there will be some reduction in the overall capacitance and thus sensitivity of the device that is a result of the reduction in the amount of electrode material provided on the flexible membrane. The reduced signal charge sensitivity may impair the signal-to-noise ratio achievable.

FIG. 4 shows a cross section of a first example comprising a membrane 301 and a membrane electrode 302 having a plurality of openings 313 formed therein. In this example the size of the openings, and thus the exposed surface area of the flexible membrane, increases from a region at the centre of the flexible membrane towards the outer region of the membrane. The centre of the membrane is indicated by dashed line C. The openings closest to the centre of the membrane have a size a₁ and can be considered to form a first group R₁, the openings surrounding the first group have a size a₂ and can be considered to form a second group R₂ and the openings towards the periphery of the membrane electrode have a size a₃ and form a third group R₃. In this example a₁<a₂<a₃.

Although the rest of the transducer structure is not shown in FIG. 4, it will be appreciated that due to the outer edges of the membrane being supported in a fixed relation relative to the substrate, the central region of the flexible membrane will exhibit the largest degree of deflection in response to a pressure differential across the membrane. In this example, therefore, it is desirable to maximise the capacitance at the central region of the membrane electrode by providing a higher ratio of the area of the membrane electrode material to the area of the membrane at the central region, whilst still alleviating the deformation of the two-layer structure by providing a lower ratio of the area of the membrane electrode material to the area of the membrane away from the central region.

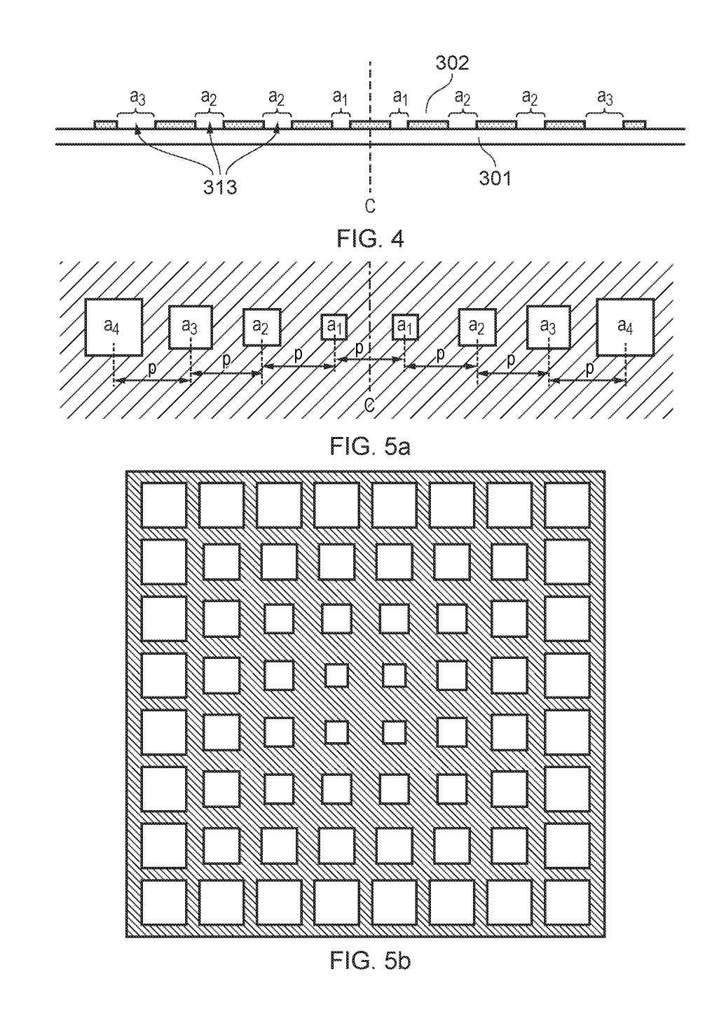

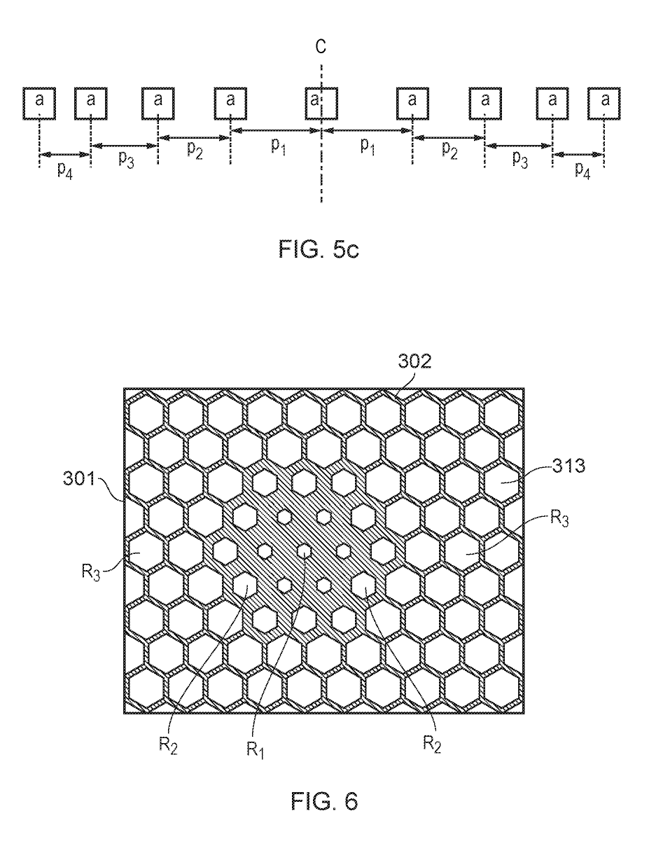

FIG. 5a illustrates the variation in the size of a series of substantially square-shaped openings that are provided diametrically across a membrane electrode according to a second example. The electrode material is indicated by the shaded region and it will be appreciated that the underlying membrane layer will be exposed in the region of each of the openings. The centre of the underlying membrane layer is indicated by dashed line C. The openings closest to the centre of the membrane have an area size a₁ and can be considered to form a first group R₁, the openings surrounding the first group have a size a₂ and can be considered to form a second group R₂, the openings surrounding the second group have a size a₃ and can be considered to form a third group R₃ and the openings towards the periphery of the membrane electrode have a size a4 and form a fourth group R₄. In this example a₁<a₂<a₃<a₄. In this example, the distance or pitch P between the centre points of adjacent openings is substantially constant whilst the area of the openings increases radially away from the centre. It will be appreciated that the electrode to membrane area radio is greatest at the central region of the electrode and gets smaller away from the central region. In other words the area of conductive material per unit area is greatest at the central region and decreases towards the periphery of the membrane electrode. FIG. 5b is a 2-dimensional illustration of the example shown in FIG. 5a.

FIG. 5c illustrates the variation in the size of a series of substantially square-shaped openings that are provided diametrically across a membrane electrode according to a third example. The centre of the underlying membrane (not shown) is indicated by dashed line C. In this example the openings are of substantially uniform size whilst the pitch distance P between the centre points of adjacent openings varies radially from the centre of the electrode towards the periphery of the electrode. In this example, the pitch distance at a central region of the electrode is greatest and the distance between adjacent openings is P1. The pitch distance decreases away from the central region such that P1>P2>P3>P4. Thus, it will be appreciated that the electrode to membrane area ratio is greatest at the central region of the electrode and gets smaller away from the central region. In other words the area of conductive material per unit area is greatest at the central region and decreases towards the periphery of the membrane electrode.

It will be appreciated that further examples are envisaged in which the pitch distance increases away from the centre whilst the size of the openings increases by enough so that the ratio of an area of the conducive material relative to an area of the openings still decreases from a first said ratio in a first region at or near a central region of the membrane layer to a second said ratio in a second region laterally outside the first region.

FIG. 6 shows a partial plan view of a fourth example comprising a membrane 301 and a membrane electrode 302 having a plurality of openings 313 formed therein. In this example the size of the openings, and thus the exposed surface area of the flexible membrane, increases from a region at the centre of the flexible membrane towards the outer region of the membrane. In this example the openings are generally hexagonal in shape. The pitch distance is substantially constant. The membrane electrode comprises three groups of openings. The first group of openings R₁ which are clustered at the centre of the illustrated membrane electrode are the smallest in size. The second group of openings R₂, which surround the first group of openings are slightly larger than the openings of the first group. The third group of openings R₃ surround the second group of openings and are the largest in size. Each of the groups R₁, R₂ and R₃ can be considered to belong to a particular region of the membrane electrode. Thus, the first group of openings R1 belong to a first, central region of the membrane electrode, the second group of openings belong to a second region of the membrane that is radially or laterally outside the first region, and the third group of openings belongs to a third region of the membrane that is radially outside the second region towards the periphery of the membrane electrode (not shown).

Thus, the membrane electrode layer may be considered to comprise a lattice of conductive material, wherein the lattice comprises a plurality of openings and wherein pitch of the lattice and/or the size of the openings varies from a central region of the membrane electrode to a region laterally outside the central region. The variation of the pitch and/or size of the openings is such that the ratio of an area of the conductive material relative to an area of the openings decreases from a first said ratio in a first region at or near a central region of the membrane layer to a second said ratio in a second region laterally outside the first region.

The examples described herein relate to a patterned membrane electrode having a plurality of openings. The size of the openings varies across the electrode. For example, the distance across the openings may be of the order of 10 μm and may vary between 8 μm and 40 μm in different regions of the membrane electrode. The distance between the electrodes of the MEMS transducer, known as the vertical inter-electrode gap distance—will typically be of the order of 2 μm. Thus, the distance across the openings may be e.g. between 5 times and 20 times the inter-electrode gap distance, or e.g. between 5 times and 10 times the inter-electrode gap distance.

The openings can be seen as an area of absence of electrode material (but at least partly bounded by electrode material), where there is still continuous material of the flexible membrane, i.e. there is a hole in the membrane electrode material only and not the flexible membrane. The openings in the membrane electrode do not necessarily correspond to holes in the membrane and thus the openings can be seen as an area of absence of electrode material (but at least partly bounded by electrode material), where there is still continuous material of the flexible membrane, i.e. there is a hole in the membrane electrode material only and not the flexible membrane.

The openings in the membrane electrode may preferably be arranged so that these openings, i.e. the areas of absence of membrane electrode material, are at least partly aligned with the holes in the back-plate, e.g. acoustic holes. As the acoustic holes are present throughout the whole back-plate, at least some of the acoustic holes in the back-plate correspond, whether in whole or in part, to holes in the back-plate electrode, i.e. areas of absence of back-plate electrode. The openings in the membrane electrode and the holes in the back-plate electrode are aligned, partially or wholly, in a traverse direction, i.e. a direction normal to the membrane. As used herein the term normal to the membrane shall mean a direction which is substantially normal to the plane defined by the bound edges of the membrane. Obviously in use the membrane may deflect and the direction of the local normal to part of the membrane may vary, but the direction normal to the whole membrane can still be seen as the direction normal to the plane of including the fixed edges of the membrane.

A MEMS transducer according to the examples described here may comprise a capacitive sensor, for example a microphone.

A MEMS transducer according to the examples described here may further comprise readout circuitry, for example wherein the readout circuitry may comprise analogue and/or digital circuitry such as a low-noise amplifier, voltage reference and charge pump for providing higher-voltage bias, analogue-to-digital conversion or output digital interface or more complex analogue or digital signal processing. There may thus be provided an integrated circuit comprising a MEMS transducer as described in any of the examples herein.

One or more MEMS transducers according to the examples described here may be located within a package. This package may have one or more sound ports. A MEMS transducer according to the examples described here may be located within a package together with a separate integrated circuit comprising readout circuitry which may comprise analogue and/or digital circuitry such as a low-noise amplifier, voltage reference and charge pump for providing higher-voltage bias, analogue-to-digital conversion or output digital interface or more complex analogue or digital signal processing.

A MEMS transducer according to the examples described here may be located within a package having a sound port.

According to another aspect, there is provided an electronic device comprising a MEMS transducer according to any of the examples described herein. An electronic device may comprise, for example, at least one of: a portable device; a battery powered device; an audio device; a computing device; a communications device; a personal media player; a mobile telephone; a games device; and a voice controlled device.

According to another aspect, there is provided a method of fabricating a MEMS transducer as described in any of the examples herein. According to one example there is provided a method of fabricating a MEMS transducer comprising forming a membrane layer;

forming a layer of conductive material on the surface of the membrane layer to form a membrane electrode;
patterning the membrane electrode to provide a plurality of openings therein, wherein a ratio of an area of the conductive material relative to an area of the openings decreases from a first said ratio in a first region at or near a central region of the membrane layer to a second said ratio in a second region laterally outside the first region. Preferably the step of patterning the membrane electrode comprises a photolithographic processing step which uses a patterned photomask.

Although the various examples describe a MEMS capacitive microphone, the present examples are also applicable to any form of MEMS transducers other than microphones, for example pressure sensors or ultrasonic transmitters/receivers. Examples described herein may be usefully implemented in a range of different material systems, however the examples described herein are particularly advantageous for MEMS transducers having membrane layers comprising silicon nitride.

In the examples described above it is noted that references to a transducer element may comprise various forms of transducer element. For example, a transducer element may comprise a single membrane and back-plate combination. In another example a transducer element comprises a plurality of individual transducers, for example multiple membrane/back-plate combinations. The individual transducers of a transducer element may be similar, or configured differently such that they respond to acoustic signals differently, e.g. the elements may have different sensitivities. A transducer element may also comprises different individual transducers positioned to receive acoustic signals from different acoustic channels.

It is noted that in the examples described herein a transducer element may comprise, for example, a microphone device comprising one or more membranes with electrodes for read-out/drive deposited on the membranes and/or a substrate or back-plate. In the case of MEMS pressure sensors and microphones, the electrical output signal may be obtained by measuring a signal related to the capacitance between the electrodes. The examples are also intended embrace a transducer element being a capacitive output transducer, wherein a membrane is moved by electrostatic forces generated by varying a potential difference applied across the electrodes, including examples of output transducers where piezo-electric elements are manufactured using MEMS techniques and stimulated to cause motion in flexible members.

It is noted that the examples described above may be used in a range of devices, including, but not limited to: analogue microphones, digital microphones, pressure sensor or ultrasonic transducers. The examples described herein may also be used in a number of applications, including, but not limited to, consumer applications, medical applications, industrial applications and automotive applications. For example, typical consumer applications include portable audio players, wearable devices, laptops, mobile phones, PDAs and personal computers. Examples may also be used in voice activated or voice controlled devices. Typical medical applications include hearing aids. Typical industrial applications include active noise cancellation. Typical automotive applications include hands-free sets, acoustic crash sensors and active noise cancellation.

It should be noted that the above-mentioned examples illustrate rather than limit the invention, and that those skilled in the art will be able to design many alternative examples without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference signs in the claims shall not be construed so as to limit their scope.

1. A MEMS transducer comprising a membrane layer and a membrane electrode formed of a conductive material on a surface of the membrane layer, the membrane electrode having a plurality of openings provided therein, wherein a ratio of an area of the conductive material relative to an area of the openings decreases from a first said ratio in a first region at or near a central region of the membrane layer to a second said ratio in a second region laterally outside the first region.

2. A MEMS transducer as claimed in claim 1, wherein the openings provided in the first region of the membrane electrode are a different size to the openings in the second region of the membrane electrode.

3. A MEMS transducer as claimed in claim 2, wherein the openings provided in the first region are smaller than the openings provided in the second region.

4. A MEMS transducer as claimed in claim 1, wherein a pitch distance between adjacent openings in the first region is different to the pitch distance between adjacent openings in the second region of the membrane electrode.

5. A MEMS transducer as claimed in claim 4, wherein the pitch distance between openings in the first region is greater than the pitch distance between openings in the second region.

6. A MEMS transducer as claimed claim 5, wherein the openings provided in the first region are the same size as the openings provided in the second region.

7. A MEMS transducer as claimed in claim 1, the membrane electrode comprising two or more additional regions in addition to the first region.

8. A MEMS transducer as claimed in claim 7, wherein each of the additional regions are arranged concentrically around the first region and wherein the ratio of the area of the conductive material relative to the area of the openings decreases from said first ratio at said first region towards the periphery of the membrane electrode.

9. A MEMS transducer as claimed in claim 1, the transducer further comprising a substrate having a cavity provided therein, wherein the membrane layer overlies the cavity and wherein the central region of the membrane layer overlies the centre of the substrate cavity.

10. A MEMS transducer as claimed in claim 1, comprising a back-plate structure wherein the flexible membrane is supported with respect to said back-plate structure.

11. A MEMS transducer as claimed in claim 10 wherein said back-plate structure comprises a plurality of holes through the back-plate structure and wherein at least a part of the area of at least one opening in the membrane electrode corresponds to the area of at least one back-plate hole, in a direction normal to the membrane.

12. A MEMS transducer as claimed in claim 1, wherein the openings are circular and/or polygonal in shape.

13. A MEMS transducer as claimed in claim 1, wherein the membrane electrode comprises a lattice structure.

14. A MEMS transducer as claimed in claim 1, wherein the membrane layer and the membrane electrode form a two-layer structure.

15. A MEMS transducer as claimed in claim 1, wherein the membrane electrode comprises a single layer of conductive material formed on the surface of the membrane.

16. A MEMS transducer as claimed in claim 1, wherein the flexible membrane layer comprises silicon nitride.

17. A MEMS transducer as claimed in claim 1, wherein the membrane electrode comprises aluminium, aluminium-silicon alloy or titanium nitride.

18. A MEMS transducer as claimed in claim 1, wherein said transducer comprises a capacitive sensor such as a capacitive microphone.

19. A MEMS transducer as claimed in claim 18, further comprising readout circuitry, wherein the readout circuitry may comprise analogue and/or digital circuitry.

20. A MEMS transducer as claimed in claim 1, wherein the transducer is located within a package having a sound port.

21. An electronic device comprising a MEMS transducer as claimed in claim 1, wherein said device is at least one of: a portable device; a battery powered device; an audio device; a computing device; a communications device; a personal media player; a mobile telephone; a games device; and a voice controlled device.

22. A membrane electrode for MEMS transducer, the membrane electrode comprising a lattice of conductive material, wherein the lattice comprises a plurality of openings each opening having a diametric size and a pitch which represents the distance between the centre of adjacent openings, and wherein the pitch of the lattice and/or the size of the openings varies from a central region of the membrane electrode to a region laterally outside the central region.

23. A membrane electrode as claimed in claim 22, wherein the variation of the pitch and/or size of the openings is such that the ratio of an area of the conducive material relative to an area of the openings decreases from a first said ratio in a first region at or near a central region of the membrane layer to a second said ratio in a second region laterally outside the first region.

24. A method of fabricating a MEMS transducer comprising;
forming a membrane layer;
forming a layer of conductive material on the surface of the membrane layer to form a membrane electrode; and
patterning the membrane electrode to provide a plurality of openings therein, wherein a ratio of an area of the conductive material relative to an area of the openings decreases from a first said ratio in a first region at or near a central region of the membrane layer to a second said ratio in a second region laterally outside the first region.
